(19) United States
(12) Patent Application Publication
(10) Pub. No.: US 2015/0261024 A1
(43) Pub. Date: Sep. 17, 2015

(54) Electro-Optic Modulators and Thin Film Transistor Array Test Apparatus Including the Same

(71) Applicants: Samsung Electronics Co., Ltd., Suwon-si (KR); Samsung Display Co, Ltd., Yongin-si (KR)

(72) Inventors: Chi-youn Chung, Seoul (KR); Young-jin Noh, Ansan-si (KR); Eun-ah Park, Yongin-si (KR); Ji-min Lee, Seoul (KR); Sung-mo Gu, Daegu (KR)

(21) Appl. No.: 14/596,907

(22) Filed: Jan. 14, 2015

(30) Foreign Application Priority Data
Mar. 13, 2014 (KR) 10-2014-0029766

(51) Int. Cl. G02F 1/1334; G01R 31/26; G02F 1/1335; G02F 1/1339; G02F 1/13; G02F 1/1343

(52) U.S. Cl. CPC G02F 1/1334; G02F 1/1309; G02F 1/13439; G02F 1/133553; G02F 1/1339; G01R 31/2621; G02F 2001/13345

(57) ABSTRACT

An electro-optic modulator includes an electro-optic sensor layer including a liquid crystal stabilized by a polymer network having a three-dimensional mesh structure that extends from a first surface of the electro-optic sensor layer to second surface of the electro-optic sensor layer opposite the first surface, a transparent electrode layer on the first surface of the electro-optic sensor layer, and a reflective layer on the second surface of the electro-optic sensor layer. A thin film transistor (TFT) array test apparatus includes a light source, an electro-optic modulator including an electro-optic sensor layer formed of a polymer network liquid crystal (PNLC), a power supply that applies a voltage between a transparent electrode layer of the electro-optic modulator and a plurality of pixel electrodes, and a reflected light sensor that measures light reflected from the electro-optic modulator.

### CROSS-REFERENCE TO RELATED APPLICATIONS

This application claims the benefit of Korean Patent Application No. 10-2014-0029766, filed on Mar. 13, 2014, in the Korean Intellectual Property Office, the disclosure of which is incorporated herein in its entirety by reference.

### BACKGROUND

The inventive concepts relate to modulators and electrical test apparatus including modulators, and more particularly, to electro-optic modulators and thin film transistor (TFT) array test apparatus for testing a TFT array used in the manufacture of flat panel displays.

During the manufacturing of flat panel displays, such as liquid crystal displays (LCD) and organic light-emitting diode (OLED) displays, TFT arrays in the displays may be electronically tested. As the area of flat panel display panels increases, various test apparatuses for accurately testing TFT arrays have been proposed. In order to perform a test of a TFT array, a voltage distribution across the TFT array is measured by using a modulator that modulates optical characteristics depending on the voltage distribution of the TFT array substrate surface. As the size of pixels of a TFT array decreases and the pixel density of a TFT array increases, it has become increasingly difficult to manufacture a test apparatus by which defects can be accurately detected in TFT arrays.

### SUMMARY

Some embodiments provide an electro-optic modulator having a structure that may improve defect detection performance when testing a thin film transistor (TFT) array including pixels having a fine pitch.

Some embodiments may also provide a TFT array test apparatus including an electro-optic modulator having a structure that may improve defect detection performance when testing a TFT array including pixels having a fine pitch.

According to an aspect of the inventive concept, there is provided an electro-optic modulator including an electro-optic sensor layer formed of a polymer network liquid crystal (PNLC) including a liquid crystal stabilized by a polymer network having a three-dimensional mesh structure from a first surface of the electro-optic sensor layer to a second surface of the electro-optic sensor layer that is opposite to the first surface of the electro-optic sensor layer, a transparent electrode layer on a first surface of the electro-optic sensor layer, and a reflective layer on the second surface of the electro-optic sensor layer.

At least one of the transparent electrode layer and the reflective layer may directly contact the polymer network of the electro-optic sensor layer.

The electro-optic modulator may further include an adhesion reinforcing layer interposed between the electro-optic sensor layer and at least one of the transparent electrode layer and the reflective layer.

The adhesion reinforcing layer may be a silicon oxide layer.

The reflective layer may be an insulating layer including metal nanoparticles.

The reflective layer may include a plurality of plasmon particles each having a size of about 10 nm to about 500 nm.

Each of the plurality of plasmon particles may include a composite shell, the composite shell formed of a metal core and an insulating shell surrounding the metal core, or formed of an insulating core and a metal shell surrounding the insulating core.

The reflective layer may include an inner surface facing the electro-optic sensor layer and an outer surface that is opposite to the inner surface, and the electro-optic modulator may further include a protective coating layer directly contacting the outer surface of the reflective layer.

The electro-optic modulator may further include a spacer interposed between the transparent electrode layer and the reflective layer, the spacer defining a region of the electro-optic sensor layer between the transparent electrode layer and the reflective layer.

The thickness of the spacer may be equal to that of the electro-optic sensor layer.

The transparent electrode layer may include an inner surface facing the electro-optic sensor layer and an outer surface that is opposite to the inner surface, and the electro-optic modulator may further include an optical glass covering the outer surface of the transparent electrode layer.

According to another aspect of the inventive concept, there is provided a thin film transistor (TFT) array test apparatus including a light source, an electro-optic modulator including an electro-optic sensor layer, a transparent electrode layer on the electro-optic sensor layer, and a reflective layer on the electro-optic sensor layer opposite the transparent electrode layer. The electro-optic modulator reflects light, received from the light source, through the electro-optic sensor layer responsive to a voltage distribution of each of a plurality of pixel electrodes forming a TFT array of a test target object. The electro-optic sensor layer is formed of a polymer network liquid crystal (PNLC) including a liquid crystal stabilized by a polymer network having a three-dimensional mesh structure from a first surface of the electro-optic sensor layer to a second surface of the electro-optic sensor layer. test apparatus further includes a power supply configured to apply a voltage between the transparent electrode layer and the plurality of pixel electrodes, and a reflected light sensor configured to measure light reflected from the electro-optic modulator and generate image information depending on the size of a voltage in each of the plurality of pixel electrodes, based on the measured reflected light.

The transparent electrode layer and the reflective layer may directly contact the polymer network of the electro-optic sensor layer.

The electro-optic modulator may further include a first adhesion reinforcing layer interposed between the electro-optic sensor layer and the reflective layer and a second adhesion reinforcing layer interposed between the electro-optic sensor layer and the transparent electrode layer.

The TFT array test apparatus may further include an image processor configured to analyze the image information generated by the reflected light sensor to thereby detect the voltage distribution of each of the plurality of pixel electrodes.

An electro-optic modulator according to another aspect includes a transparent electrode layer, a reflective layer on the transparent electrode layer, and a spacer between the transparent electrode layer and the reflective layer. The spacer contacts edge portions of the transparent electrode layer and the reflective layer to define a region within the edge portions between the transparent electrode layer and the reflective layer. The electro-optic modulator further includes an electro-optic sensor layer in the region defined by the spacer between the transparent electrode layer and the reflective layer. The electro-optic sensor layer includes a liquid crystal stabilized by a polymer network having a three-dimensional mesh structure that extends from a first surface of the electro-optic sensor layer proximate the transparent electrode layer to a second surface of the electro-optic sensor layer proximate the reflective layer.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a main structure of an electro-optic modulator according to some embodiments of the inventive concepts;

FIGS. 2A and 2B each are a more detailed diagram of an electro-optic sensor layer illustrated in FIG. 1;

FIG. 3 is a plan view of a spacer included in the electro-optic modulator of FIG. 1;

FIG. 4 is a cross-sectional view of a main structure of an electro-optic modulator according to another embodiment of the inventive concepts;

FIGS. 5A to 5M are cross-sectional views illustrated according to a process sequence of a method of manufacturing an electro-optic modulator, according to some embodiments of the inventive concepts;

FIGS. 6A to 6I are cross-sectional views illustrated according to a process sequence of a method of manufacturing an electro-optic modulator, according to another embodiment of the inventive concepts;

FIG. 7 is a diagram of a simplified main structure of a thin film transistor (TFT) array test apparatus according to some embodiments of the inventive concepts; and

FIG. 8 is a block diagram of a liquid crystal display device according to some embodiments of the inventive concepts.

### DETAILED DESCRIPTION OF THE EMBODIMENTS

The inventive concepts will now be described more fully with reference to the accompanying drawings, in which exemplary embodiments of the inventive concepts are shown. In the drawings, the same elements are denoted by the same reference numerals and a repeated explanation thereof will not be given.

Hereinafter, the inventive concepts will be described more fully with reference to the accompanying drawings, in which exemplary embodiments of the inventive concepts are shown. The inventive concepts may, however, be embodied in many different forms and should not be construed as being limited to the embodiments set forth herein; rather these embodiments are provided so that this disclosure will be thorough and complete, and will fully convey the concept of the inventive concepts to one of ordinary skill in the art.

It will be understood that, although the terms “first”, “second”, “third”, etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of exemplary embodiments. For example, a first element may be referred to as a second element, and likewise, a second element may be referred to as a first element without departing from the scope of the inventive concept.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

It should also be noted that in some alternative implementations, operations may be performed out of the sequences depicted in the flowcharts. For example, two operations shown in the drawings to be performed in succession may in fact be executed substantially concurrently or even in reverse of the order shown, depending upon the functionality/acts involved.

Modifications of shapes illustrated in the accompanying drawings may be estimated according to manufacturing processes and/or process variation. Accordingly, embodiments of the inventive concepts should not be construed as being limited to a specific shape of an area illustrated in the present specification and should include a change in shape which may be caused in manufacturing processes.

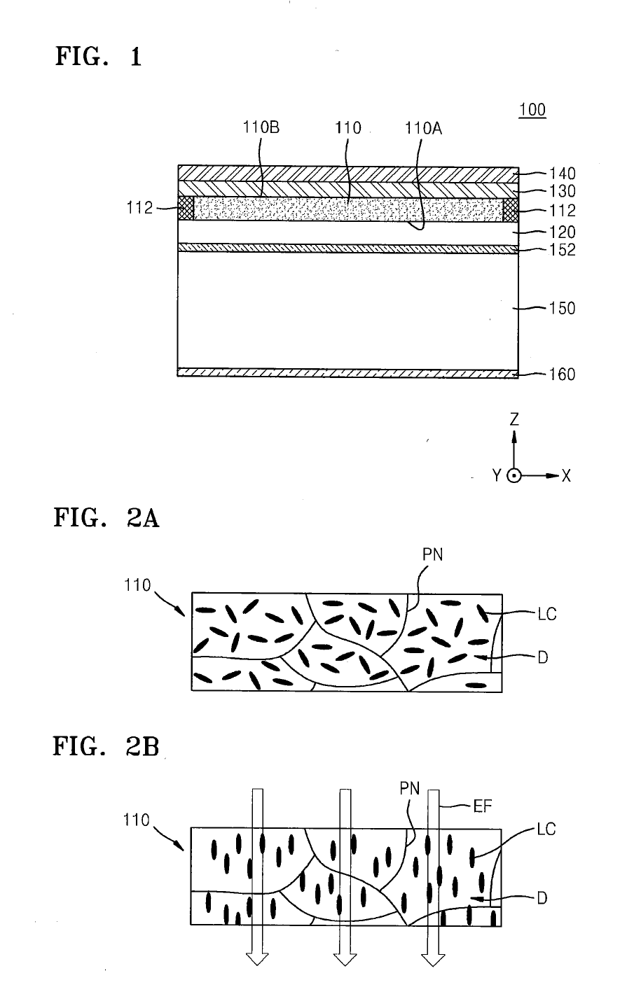

FIG. 1 is a cross-sectional view of a main structure of an electro-optic modulator 100 according to some embodiments of the inventive concept.

Referring to FIG. 1, the electro-optic modulator 100 includes an electro-optic sensor layer 110, a transparent electrode layer 120 on a first surface 110A of the electro-optic sensor layer 110, and a reflective layer 130 on a second surface 110B that is opposite to the first surface 110A of the electro-optic sensor layer 110. The transparent electrode layer 120 may cover an entirety of the first surface 110A of the electro-optic sensor layer 110, although the invention is not limited thereto. Similarly the reflective layer 130 may cover an entirety of the second surface 110B of the electro-optic sensor layer 110, although the invention is not limited thereto.

The electro-optic sensor layer 110 is formed of a polymer network liquid crystal (PNLC) including a liquid crystal material that is stabilized by a polymer network having a three-dimensional net or mesh structure that may extend from an first surface of the electro-optic sensor layer 110 to a second surface thereof opposite the first surface. Accordingly, the PNLC may be exposed at both the first surface 110A and the second surface 110B of the electro-optic sensor layer 110.

FIGS. 2A and 2B are more detailed diagrams of the electro-optic sensor layer 110 illustrated in FIG. 1.

Referring to FIGS. 2A and 2B, the electro-optic sensor layer 110 includes a PNLC layer including a polymer network PN and a liquid crystal material LC that is mechanically stabilized by the polymer network PN.

The polymer network PN has a three-dimensional structure, and a plurality of domains D are formed by the polymer network PN. Each of the plurality of domains D is a space that is formed by a net-shaped structure of the polymer network PN and may denote a liquid crystal area. The liquid crystal material LC is distributed in the plurality of domains D formed by the polymer network PN. The polymer network PN may be distributed in a random form, although the invention is not limited thereto. For example the polymer network may have a regular or semi-regular structure.

As illustrated in FIG. 2A, when an electric field is not applied to the electro-optic sensor layer 110, liquid crystal molecules forming the liquid crystal material LC are are distributed in random directions. When the liquid crystal molecules are arranged in random directions, they function to scatter light that is incident on the electro-optic sensor layer 110.

In contrast, as illustrated in FIG. 2B, when an electric field EF is applied to the electro-optic sensor layer 110, liquid crystal molecules forming the liquid crystal material LC become arranged parallel to the electric field EF. When the liquid crystal molecules are arranged in such a manner, they function to make the electro-optic sensor layer 110 transparent.

The polymer network PN and the liquid crystal material LC each may include one or more materials.

In some embodiments, the polymer network PN may be obtained from a compound including photosensitive moiety.

For example, the polymer network PN may be formed of a material that results from a cross-linking reaction or a polymerization reaction of a compound including (meth)acrylate, poly(meth)acrylate, fluorinated acrylate, or a combination thereof. However, the material of the polymer network PN is not limited thereto.

The liquid crystal material LC may be phase-separated in the polymer network PN, and may be formed of a compound that may exist in an oriented state in the polymer network PN. For example, the liquid crystal material LC may include a nematic liquid crystal, a cholesteric liquid crystal, a smectic liquid crystal, a ferroelectric liquid crystal, or a combination thereof. However, the inventive concepts are not limited thereto.

The liquid crystal material LC is phase-separated and thus is not combined with the polymer network PN. In addition, when a voltage is externally applied to the liquid crystal material LC, the orientation of the liquid crystal molecules may be changed. To this end, the liquid crystal material LC may be a compound that does not have a group for polymerization or a group for cross-linking reaction.

The liquid crystal sensitivity of the electro-optic sensor layer 110 is a main factor that determines the performance of the electro-optic modulator 100. In order to improve a change in transmittance of the liquid crystal layer in the electro-optic sensor layer 110 in response to a minute voltage change (hereinafter, referred to as “liquid crystal sensitivity”), the material and phase separation condition of the electro-optic sensor layer 110 may be appropriately selected.

In some embodiments, a dielectric anisotropy of the liquid crystal material LC may be from about 7 to about 10. In some embodiments, the refractive index anisotropy of the liquid crystal material LC may be from about 0.2 to about 0.3.

The size of of the domains (hereinafter, referred to as “mesh size”) D formed by the polymer network PN may be about 1 μm or less. If the mesh size of the polymer network PN exceeds 1 μm, a light-scattering effect may be reduced when an electric field is not applied to the liquid crystal layer.

In addition, a mesh density of the polymer network PN may be about 100 or more per 100 square micrometers to obtain a sufficient light-scattering effect when an electric field is not applied to the liquid crystal layer.

The thickness of the electro-optic sensor layer 110 may be determined in consideration of light-scattering and a dielectric constant correlation with an air gap. Unless specifically defined, the term “thickness” used in the present specification denotes a size in the Z direction (vertical direction) of FIG. 1. In some embodiments, the electro-optic sensor layer 110 may have a thickness of about 20 μm to about 25 μm.

When an electric field is applied to the electro-optic sensor layer 110, the light transmittance of incident light on the electro-optic sensor layer 110 may be about 80% or more. When an electric field is not applied to the electro-optic sensor layer 110, the light transmittance in the electro-optic sensor layer 110 may be about 5% or less of incident light, thereby increasing a contrast ratio. If the thickness of the electro-optic sensor layer 110 is 20 μm, the driving voltage at which the light transmittance of the electro-optic sensor layer 110 becomes 90% of a maximum light transmittance thereof (such driving voltage referred to herein as the “V90” driving voltage), may be 10 volts or less. When the power is in an ON state, a haze may be about 2% or less to suppress a blurring phenomenon that may occur when capturing a fine pattern image.

At least one of the transparent electrode layer 120 and the reflective layer 130 may contact the electro-optic sensor layer 110 directly. In FIG. 1, the transparent electrode layer 120 is in direct contact with the first surface 110A of the electro-optic sensor layer 110 and the reflective layer 130 is in direct contact with the second surface 110B of the electro-optic sensor layer 110. However, the inventive concepts are not limited thereto. For example, at least one selected from the transparent electrode layer 120 and the reflective layer 130 may be separated from the electro-optic sensor layer 110 by a predetermined distance so as not to contact the electro-optic sensor layer 110. In addition, another material layer may be interposed between the transparent electrode layer 120 and the reflective layer 130. A more specific example will be described with reference to FIG. 4 below.

The transparent electrode layer 120 may include a transparent conductive oxide (TCO). In some embodiments, the transparent electrode layer 120 may include indium tin oxide (ITO), aluminum zinc oxide (AZO), indium zinc oxide (IZO), ZnO, GZO (ZnO:Ga), In₂O₃, SnO₂, CdO, CdSnO₄, Ga₂O₃, or a combination thereof. In some other embodiments, the transparent electrode layer 120 may include indium oxide containing an additive, such as Mg, Ag, Zn, Sc, Hf, Zr, Te, Se, Ta, W, Nb, Cu, Si, Ni, Co, Mo, Cr, Sn, or a combination thereof. However, the inventive concepts are not limited thereto. In some embodiments, the transparent electrode layer 120 may have a thickness of about 25 μm to about 100 μm. However, the inventive concepts are not limited thereto.

The reflective layer 130 may be a film-shaped nonconductive thin film formed by a coating method. In some embodiments, the reflective layer 130 may be a metal-containing insulating layer that selectively reflects light corresponding to a specific wavelength due to the surface plasmon characteristics of metal nanoparticles. The reflective layer 130 may include a plurality of plasmon particles that are formed of metal nanoparticles in which surface plasmon may easily occur. In some embodiments, each of the plurality of plasmon particles may have a dome-shaped structure, a sphere-shaped structure, an egg-shaped structure, a bar-shaped structure, or a pyramid-shaped structure. However, the inventive concepts are not limited thereto. In some embodiments, each of the plurality of plasmon particles may include a composite shell including a metal core and an insulating shell surrounding the metal core, or a composite shell including an insulating core and a metal shell surrounding the insulating core. Each of the plurality of plasmon particles may have a size of about 10 nm to 500 nm. In some embodiments, each of the plurality of plasmon particles may include one or more of Ag, Au, Cu, Pt, Al, and alloys thereof. In some embodiments, a space between each the plurality of plasmon particles in the reflective layer 130 may be about 700 nm or less.

The plurality of plasmon particles may have various refractive indexes in response to an electric field that is applied to the plurality of plasmon particles. The size and shape of the plurality of plasmon particles may be selected based on a desired reflective light wavelength. In some embodiments, the reflective layer 130 may be formed to reflect light in the visible light range. To this end, metal particles included in the reflective layer 130 may have the form of nanowire particles.

The plurality of plasmon particles may be coated with a dielectric material, such as SiO₂, Al₂O₃, Si₃N₄, TiO₂, and/or ZnO, to inhibit oxidization and improve dispersibility. In this case, the thickness of a coating film of the dielectric material may be from about 1 nm to about 100 nm.

The thickness of the reflective layer 130 may be related to the wavelength of reflected light. In some embodiments, the reflective layer 130 may have a thickness that may induce the reflection of light in the visible light range. For example, the reflective layer 130 may have a thickness of about 10 μm or less, for example, a thickness of about 5 μm to about 6 μm. However, the inventive concepts are not limited thereto. By reducing the thickness of the reflective layer 130 as much as possible, a distance between the electro-optic sensor layer 110 and a test object, e.g., an electrode of a TFT array, may be reduced. Accordingly, the sensitivity of the liquid crystal material may be increased Thus, defects in pixels arranged in a TFT array having a pitch of about 30 μm or less may be more effectively detected when using the liquid crystal material in a sensor.

An outer surface of the reflective layer 130, which is opposite to an inner surface thereof which faces the electro-optic sensor layer 110, may be coated with a protective coating layer 140.

The protective coating layer 140 may directly contact the outer surface of the reflective layer 130 and may help protect the reflective layer 130 from being contaminated or damaged.

In some embodiments, the protective coating layer 140 may include an ultraviolet (UV) curable hard coating composition, such as a multi-functional acrylate, a di-functional acrylate, and/or a silicon acrylate. If necessary, the protective coating layer 140 may further include nano-particles that function as inorganic fillers, other than an ultraviolet (UV) curable hard coating composition, to improve the hardness of the protective coating layer 140.

In some other embodiments, the protective coating layer 140 may be formed of a nonconductive oxide having a relatively low dielectric constant, such as silica.

In some other embodiments, the protective coating layer 140 may be formed of a thermosetting material that hardens at a temperature that is equal to or less than room temperature, such as epoxy, urethan, and the like. The protective coating layer 140 may further include nano-particles that function as inorganic fillers, other than a thermosetting material to improve the hardness of the protective coating layer 140.

In some embodiments, the protective coating layer 140 may have a thickness in a range of about 5 μm to 6 μm. However, the inventive concepts are not limited thereto.

A spacer 112 is interposed between the transparent electrode layer 120 and the reflective layer 130 around the electro-optic sensor layer 110.

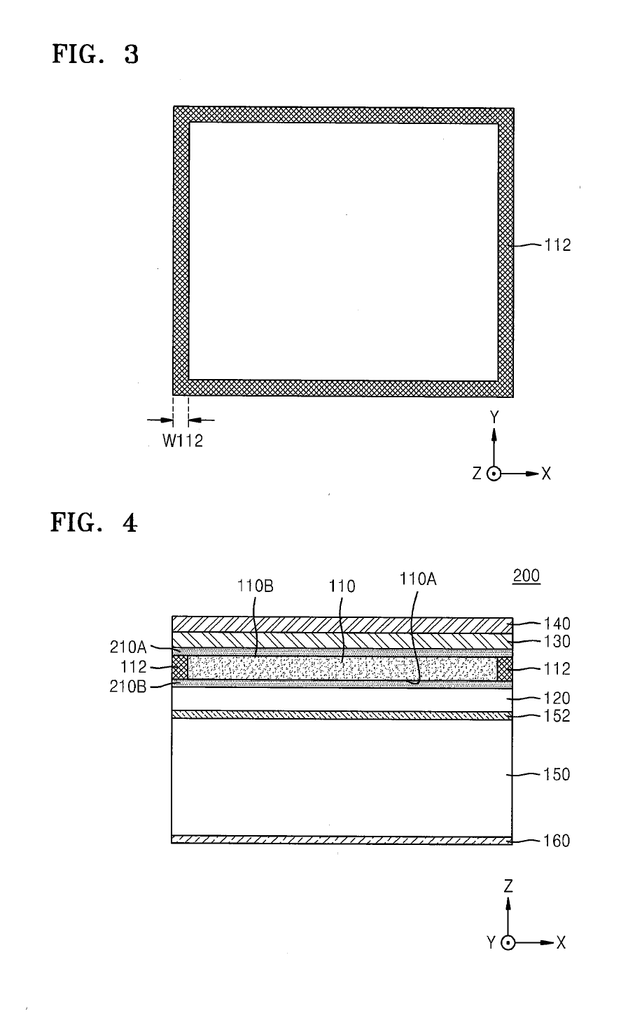

FIG. 3 is a plan view of the spacer 112 illustrated in FIG. 1.

Referring to FIGS. 1 and 3, the spacer 112 may define the region of the electro-optic sensor layer 110 between the transparent electrode layer 120 and the reflective layer 130. The spacer 112 may be formed of a material having an adhesive property. For example, the spacer 112 may be formed of silicon or acrylic resin.

In some embodiments, the spacer 112 may have a thickness that is equal to that of the electro-optic sensor layer 110. In some embodiments, the spacer 112 may have a thickness of about 20 μm to about 25 μm and a width W112 of about 1 mm to about 3 mm.

Referring again to FIG. 1, a first surface of the transparent electrode layer 120, which is opposite to a second surface thereof which faces the electro-optic sensor layer 110, may be coated/covered with an optical glass 150. The optical glass 150 may be attached to the transparent electrode layer 120 by an adhesive layer 152.

The optical glass 150 may include a BK-7 type optical glass.

An outer surface of the optical glass 150, which is opposite to an inner surface thereof that faces the electro-optic sensor layer 110, may be coated with a reflection protective layer 160.

In some embodiments, the reflection protective layer 160 may be an inorganic reflection protective layer. However, the inventive concepts are not limited thereto.

The electro-optic sensor layer 110 included in the electro-optic modulator 100 of FIG. 1 is formed of a PNLC including a liquid crystal material that is mechanically stabilized by a polymer network having a three-dimensional net or mesh structure from an outer surface of the electro-optic sensor layer 110 to an inner surface thereof. Such a structure may and not need a polymer matrix.

As a comparison example, if an electro-optic sensor layer is formed of polymer dispersed liquid crystal (PDLC) having a relatively high polymer content or includes capsulated liquid crystal droplets and a polymer matrix for fixing the capsulated liquid crystal droplets, a liquid crystal sensitivity of the electro-optic sensor layer may be reduced due to the high polymer content, and thus, there its ability to test pixels having a fine pitch may be limited.

However, since an electro-optic sensor layer 110 included in an electro-optic modulator 100 according to some embodiments includes PNLC having a relatively low polymer content and does not include a polymer matrix for fixing the PNLC, a change in liquid crystal transmittance in response to a small voltage change, that is, the liquid crystal sensitivity, may be improved. Thus, the electro-optic sensor layer 110 may be advantageously used in a structure for testing pixels having a fine pitch.

FIG. 4 is a cross-sectional view of a structure of an electro-optic modulator 200 according to further embodiments of the inventive concepts. In FIG. 4, the same reference numerals as FIGS. 1 to 3 denote the same elements as FIGS. 1 to 3. Thus, repeated descriptions thereof will not be given.

Referring to FIG. 4, the electro-optic modulator 200 includes a first adhesion reinforcing layer 210A interposed between the electro-optic sensor layer 110 and the reflective layer 130 and a second adhesion reinforcing layer 210B interposed between the electro-optic sensor layer 110 and the transparent electrode layer 120.

The first adhesion reinforcing layer 21 OA and the second adhesion reinforcing layer 210B may reinforce an adhesive strength between the electro-optic sensor layer 110 and the reflective layer 130 and an adhesive strength between the electro-optic sensor layer 110 and the transparent electrode layer 120, respectively, so that a modulator assembly having a stacked structure, in which the transparent electrode layer 120, the electro-optic sensor layer 110, and the reflective layer 130 are stacked in this order, may maintain a highly uniform thin film form. As the modulator assembly maintains a highly uniform thin film form in this manner, the performance of the electro-optic modulator 200 may be improved.

In some embodiments, the first adhesion reinforcing layer 210A and the second adhesion reinforcing layer 210B each may be formed of silicon oxide.

In some embodiments, the first adhesion reinforcing layer 210A and the second adhesion reinforcing layer 21 OB each may have a thickness that is smaller than that of the reflective layer 130.

The first adhesion reinforcing layer 210A and the second adhesion reinforcing layer 210B each may have a thickness of about 2 nm to about 100 nm. However, the inventive concepts are not limited thereto. The first adhesion reinforcing layer 210A and the second adhesion reinforcing layer 210B may be formed to have a thickness that is sufficient to secure an adhesive strength between the electro-optic sensor layer 110 and the reflective layer 130 and an adhesive strength between the electro-optic sensor layer 110 and the transparent electrode layer 120, respectively. For example, the first adhesion reinforcing layer 210A and the second adhesion reinforcing layer 210B each may have a thickness that is smaller than that of the reflective layer 130. By reducing the thicknesses of the first and second adhesion reinforcing layers 210A and 210B, the total thickness of the modulator assembly having a stacked structure, in which the transparent electrode layer 120, the electro-optic sensor layer 110, and the reflective layer 130 are stacked in this order, may be reduced, and thus, a distance between the electro-optic sensor layer 110 and a test object, e.g., an electrode of a TFT array, may be reduced. Accordingly, liquid crystal sensitivity may be improved, and thus, defects of a plurality of pixels arranged in a pitch of about 30 μm or less may be effectively detected when testing the TFT array.

In some embodiments, any one or more of the first adhesion reinforcing layer 210A and the second adhesion reinforcing layer 210B may be omitted.

In the electro-optic modulator 200 illustrated in FIG. 4, an adhesive strength for the reflective layer 130 and an adhesive strength for the transparent electrode layer 120 may be improved by the first adhesion reinforcing layer 210A and the second adhesion reinforcing layer 210B, respectively, so that the modulator assembly may maintain a highly uniform thin film form. Accordingly, the performance of the electro-optic modulator 200 may be improved.

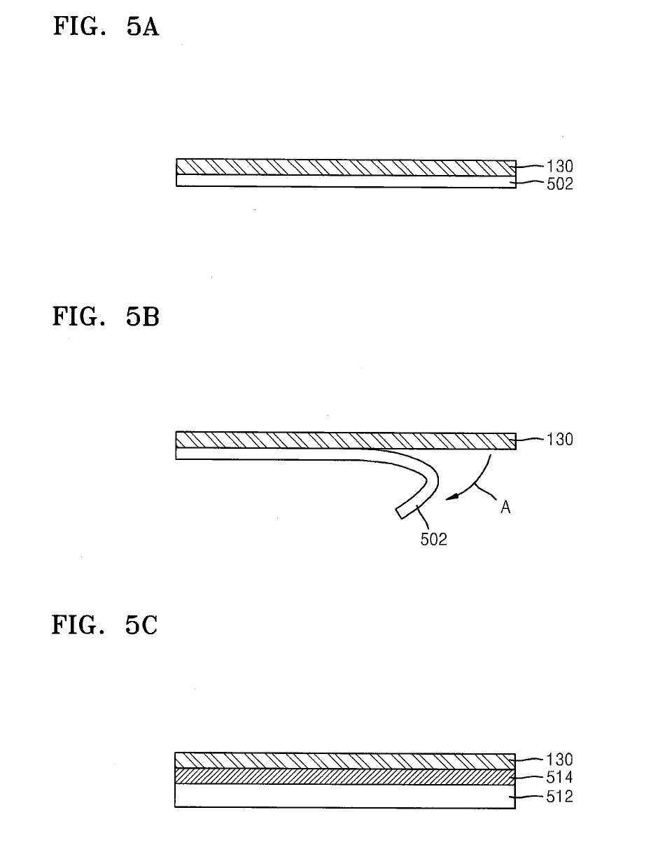

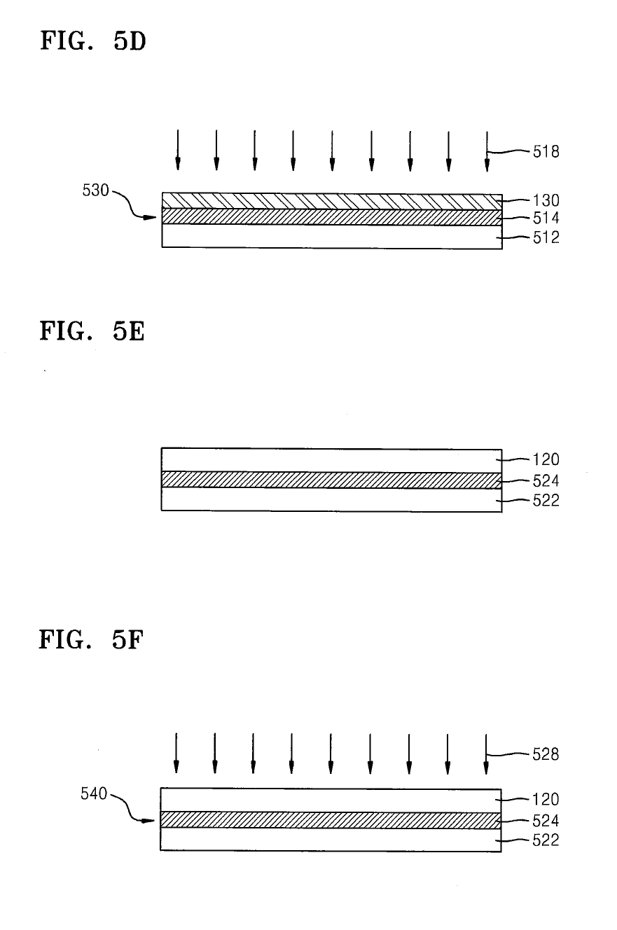

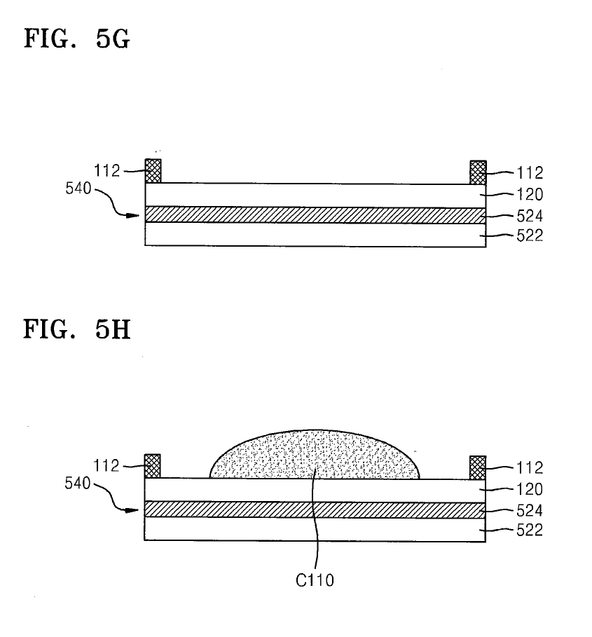

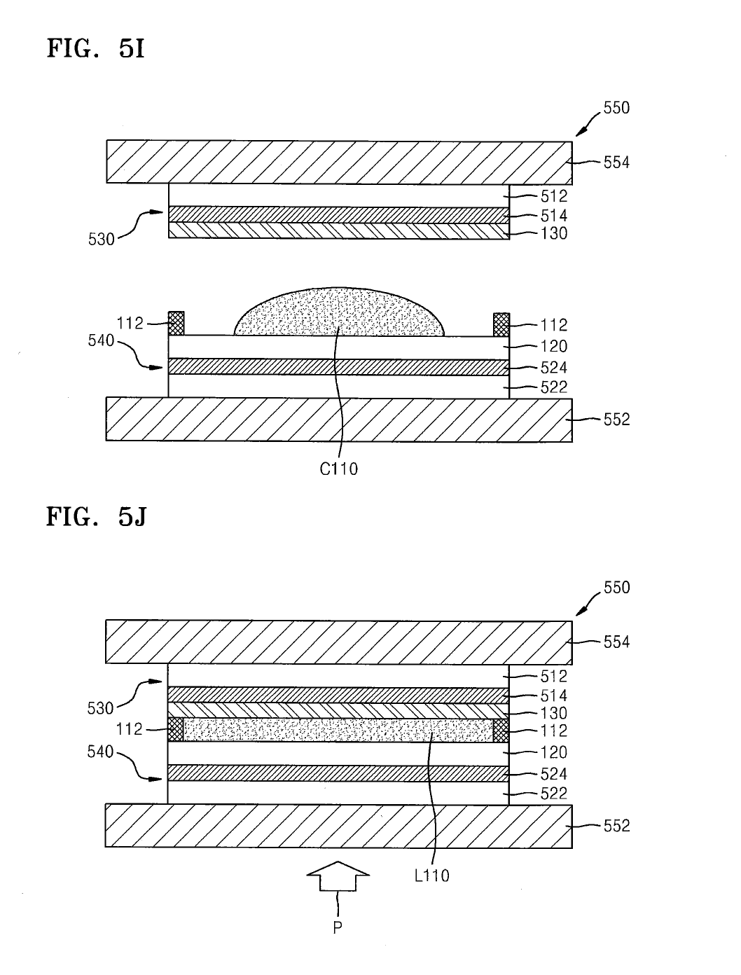

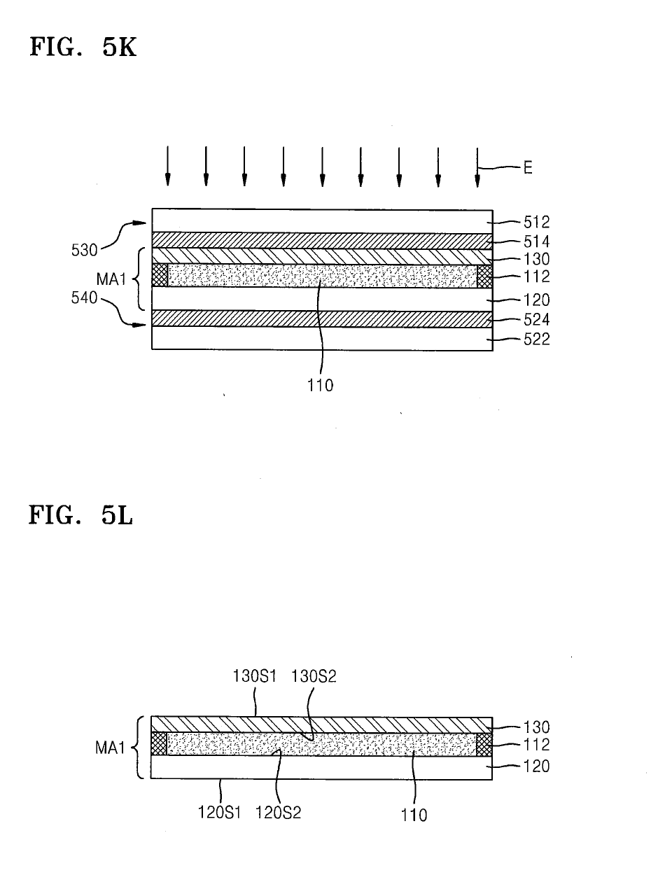

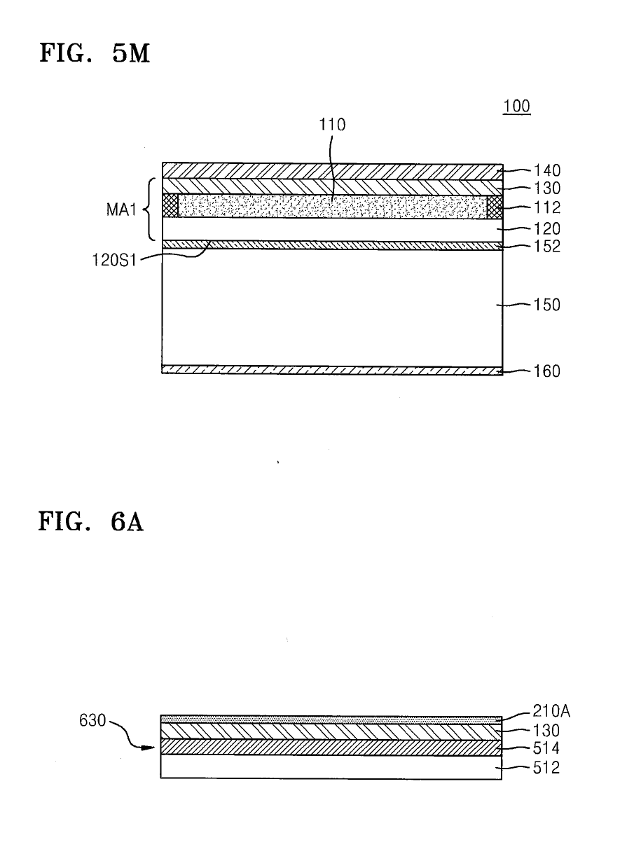

FIGS. 5A to 5M are cross-sectional views illustrating methods of manufacturing an electro-optic modulator according to some embodiments of the inventive concept. In FIGS. 5A to 5M, exemplary process steps for manufacturing the electro-optic modulator 100 of FIG. 1 are illustrated. In FIGS. 5A to 5M, the same reference numerals as FIGS. 1 to 3 denote the same elements as FIGS. 1 to 3. Thus, repeated descriptions thereof will not be given.

FIGS. 5A to 5D are cross-sectional views illustrating the formation of a reflective layer fixing structure 530 (refer to FIG. 5D).

Referring to FIG. 5A, a reflective layer 130 is formed by coating a solution including metal nanoparticles on a base substrate 502, and then drying the coated solution.

In some embodiments, the base substrate 502 may be formed of a polyester film formed of stretched polyethylene terephthalate (PET), such as Mylar® that is a commercially available product.

Metal nanoparticles may be included in the solution, and may include gold, silver, copper, aluminum, iron, nickel, titanium, tungsten, chromium, or a combination thereof. As described with respect to the reflective layer 130 with reference to FIG. 1, the metal nanoparticles each may have a form coated with a dielectric material.

The solution may include a solvent that disperses the metal nanoparticles. In some embodiments, the solvent may include, for example, water, ketone, alcohol, ether, toluene, amide, fluorine-based solvents, or glycol ether.

In addition, the solution may further include an additive, such as a surfactant, a leveling agent, an antistatic agent, or a UV absorber.

Spin coating, dipping, spray coating, or bar coating may be used as a method of coating the solution on the base substrate 502.

A coating thickness of the solution may be adjusted so that the reflective layer 130 obtained after drying has a thickness of about 10 μm or less, for example, a thickness of about 5 μm to about 6 μm.

The solution may be dried by using natural drying, blowing, or heat.

By forming the reflective layer 130 by using a coating method, the reflective layer 130 may maintain a highly uniform thin film form, may have a remarkably low probability of micro-defect generation, compared to a reflective layer formed by using a physical vapor deposition (PVD) process or an electrical beam (E-beam) evaporation process, and may exhibit excellent surface uniformity and excellent electric field transmittance. When considering that one of the main factors determining the performance of an electro-optic modulator for detecting a defective pixel of a TFT array is the uniformity of the reflective layer 130, the performance of detecting a defective pixel of a TFT array may be improved by applying the reflective layer 130 formed by a coating method to the electro-optic modulator.

Referring to FIG. 5B, the base substrate 502 is separated from the reflective layer 130. To this end, as illustrated in FIG. 5B, the base substrate 502 may be moved in the direction of an arrow A so that the base substrate 502 is separated from the reflective layer 130.

In the case of another reflective layer formed by using a PVD process, a base substrate used during a deposition process is difficult to separate, and thus, the base substrate as well as the reflective layer may be also inevitably used to form an electro-optic modulator. Accordingly, when detecting a defective pixel of a TFT array, a separation distance between an electro-optic sensor layer including a liquid crystal and an electrode of the TFT array increases by a distance corresponding to the thickness of the base substrate. When the separation distance between the electro-optic sensor layer and the electrode of the TFT array increases, the pixel detection sensitivity of the electro-optic modulator may be reduced.

In contrast, in the methods of manufacturing an electro-optic modulator according to embodiments of the inventive concept, the base substrate 502 may be removed after forming the reflective layer 130 by using a coating method. Accordingly, a separation distance between an electro-optic sensor layer including a liquid crystal and an electrode of a TFT array, i.e., a defective pixel detection target, may decrease, and thus, the defective pixel detection sensitivity may be improved.

Referring to FIG. 5C, the reflective layer 130 obtained in the process of FIG. 5B is fixed onto a first carrier substrate 512. A first carrier fixing adhesive layer 514 may be used to fix the reflective layer 130 onto the first carrier substrate 512.

In some embodiments, the first carrier substrate 512 may include glass or plastic. The first carrier substrate 512 may have a thickness of about 500 μm to about 1000 μm, for example, a thickness of about 700 μm.

In some embodiments, the first carrier fixing adhesive layer 514 may be formed of thermal sensitive adhesive (TSA). For example, the first carrier fixing adhesive layer 514 may maintain an adhesive strength at temperature of about 25° C. or more and may lose the adhesive strength thereof at temperature of about 5° C. or less. A commercially available adhesive tape (e.g., Intelimer®) may be used as the first carrier fixing adhesive layer 514.

Referring to FIG. 5D, the reflective layer fixing structure 530 may be formed by processing an exposed surface of the reflective layer 130 with UV ozone 518 while the reflective layer 130 is fixed onto the first carrier substrate 512.

By processing the exposed surface of the reflective layer 130 with the UV ozone 518, organic matter or foreign substances on the exposed surface of the reflective layer 130 may be oxidized or disassembled, and thus the surface of the reflective layer 130 may be clean. In addition, when the surface of the reflective layer 130, which is processed with the UV ozone 518, contacts another material in a subsequent process, close contact strength to the other material may be improved, and thus, an adhesive strength may be improved.

For example, when UV rays are radiated onto an oxygen molecule in the air, outer electrons of the oxygen molecule are excited due to energy impact, and thus, the oxygen molecule is disassembled into reactive oxygen atoms. The reactive oxygen atoms are combined with an oxygen molecule to thereby generate ozone having high reactivity. Since the oxidizing power of the ozone is very strong, the ozone may effectively oxidize and disassemble organic matter and foreign substances on the reflective layer 130 to thereby clean the surface of the reflective layer 130.

In some embodiments, a xenon (Xe) excimer lamp may be used as a UV light source for processing the exposed surface of the reflective layer 130 with UV ozone. The Xe excimer lamp may radiate UV rays having a short single wavelength of about 172 nm. The UV rays have an excellent light-emitting efficiency and a large oxygen absorption coefficient, and thus may generate oxygen radical or ozone at high concentration by using a small amount of oxygen and effectively dissociate a combination of organics by emitting light having a relatively short wavelength.

In some embodiments, the UV ozone processing on the reflective layer 130 may be performed for about 1 minute to about 10 minutes, for example, for about 5 minutes.

FIGS. 5E and 5F are cross-sectional views illustrating the formation of an electrode fixing structure 540 (refer to FIG. 5F).

Referring to FIG. 5E, a transparent electrode layer 120 is fixed onto a second carrier substrate 522. A second carrier fixing adhesive layer 524 may be used to fix the transparent electrode layer 120 onto the second carrier substrate 522.

In some embodiments, detailed configurations of the second carrier substrate 522 and the second carrier fixing adhesive layer 524 are the same as those of the first carrier substrate 512 and the first carrier fixing adhesive layer 514 described with reference to FIG. 5C.

Referring to FIG. 5F, the electrode fixing structure 540 is formed by processing, with UV ozone 528, an exposed surface of the transparent electrode layer 120 that is fixed onto the second carrier substrate 512.

A detailed method of the processing with the UV ozone 528 is the same as that of the processing with the UV ozone 518, which is described above with reference to FIG. 5D.

By processing the exposed surface of the transparent electrode layer 120 with the UV ozone 528, organic matter or foreign substances on the exposed surface of the transparent electrode layer 120 may be oxidized or disassembled, and thus the surface of the transparent electrode layer 120 may be clean. In addition, when the surface of the transparent electrode layer 120, which is processed with the UV ozone 528, contacts another material in a subsequent process, close contact strength to the other material may be improved, and thus, an adhesive strength may be improved.

Referring to FIG. 5G, a spacer 112 is formed in the electrode fixing structure 540 and covers an edge portion of an exposed upper surface of the transparent electrode layer 120. The spacer surrounds a central portion of the exposed upper surface of the transparent electrode 120 and defines a space above the transparent electrode 120 in which the electro-optic sensor layer 110 will be formed, as described in more detail below.

The spacer 112 may have the same shape and configuration as described with reference to FIG. 3. The thickness of the electro-optic sensor layer 110 to be formed in a subsequent process may be determined by the thickness of the spacer 112.

Referring to FIG. 5H, a PNLC composition C110 in liquid form is coated, by a predetermined amount, on an area of the upper surface of the transparent electrode layer 120, the area being limited by the spacer 112.

The amount of the PNLC composition C110 in liquid form may be determined in advance in consideration of the area that is limited by the spacer 112.

In some embodiments, the PNLC composition C110 in liquid form includes a liquid crystal and a light-sensitive compound.

The liquid crystal may include nematic liquid crystal, cholesteric liquid crystal, smectic liquid crystal, ferroelectric liquid crystal, or a combination thereof. However, the inventive concepts are not limited thereto.

For example, the light-sensitive compound may include UV curable monomer, oligomer, polymer, or a blend thereof.

In some embodiments, the light-sensitive compound may be formed of (meth)acrylate, poly(meth)acrylate, fluorinated acrylate, or a combination thereof. However, the inventive concepts are not limited thereto.

The light-sensitive compound may include at least one cross-linking or polymerization functional group that forms a network by using cross-linking or polymerization. The cross-linking or polymerization functional group may be a functional group responding to the application of heat or the application of active energy such as UV rays. The cross-linking or polymerization functional group may include a hydroxyl group, a carboxyl group, an alkenyl group such as a vinyl group or an allyl group, an epoxy group, an oxetanyl group, a vinyl ether group, a cyano group, an acryloyl group, a (meth)acryloyl group, an acryloyloxy group, or a (meth)acryloyloxy group. However, the inventive concepts are not limited thereto.

The PNLC composition C110 in liquid form may further include a cross-linking agent. The cross-linking agent is a material that may cause a cross-linking reaction according to the application of active energy such as UV rays. Multifunctional acrylate may be used as the cross-linking agent. However, the inventive concepts are not limited thereto.

The PNLC composition C110 in liquid form may further include an additive, such as a solvent, a free radical photoinitiator, a cationic initiator, a basic substance, and a surfactant, according to the need. Examples of a solvent that may be included in the PNLC composition C110 in liquid form include toluene, xylene, cyclopentanone, cyclohexanone, and the like. However, the inventive concepts are not limited thereto.

For example, a bar coating process, a comma coating process, an inkjet coating process, or a spin coating process may be used to coat the PNLC composition C110 on the area of the upper surface of the transparent electrode layer 120, the area being limited by the spacer 112, as illustrated in FIG. 5H.

Referring to FIG. 5I, in a state in which the PNLC composition C110 in liquid form is coated on the upper surface of the transparent electrode layer 120 in the electrode fixing structure 540, the electrode fixing structure 540 and the reflective layer fixing structure 530 are positioned between a lower pressing member 552 and an upper pressing member 554 of uniform pressure equipment 550. In this case, the transparent electrode layer 120 of the electrode fixing structure 540 and the reflective layer 130 of the reflective layer fixing structure 530 are positioned so as to be aligned facing each other.

Referring to FIG. 5J, a joining process is performed, by which pressure P is applied to the lower pressing member 552 so that the lower pressing member 552 moves to the upper pressing member 554 and thus the spacer 112 meets the reflective layer 130.

As a result, the PNLC composition C110 coated on the upper surface of the transparent electrode layer 120 is pressed by the reflective layer 130, and thus, a PNLC composition layer L110 in liquid form, which fills a space limited by the spacer 112, is formed between the transparent electrode layer 120 and the reflective layer 130.

The joining process may be performed under air pressure.

Since the joining process is performed in a state in which the reflective layer 130 is supported on the first carrier substrate 512 and the transparent electrode layer 120 is supported on the second carrier substrate 522, rigidity may be given to the reflective layer 130 and the transparent electrode layer 120 during the joining process.

Referring to FIG. 5K, after relieving the pressure P applied to the lower pressing member 552 (refer to FIG. 5J), the electrode fixing structure 540 and the reflective layer fixing structure 530, which are aligned facing each other with the spacer 112 and the PNLC composition layer L110 (refer to FIG. 5J) interposed therebetween, are separated from the uniform pressure equipment 550.

Then, activation energy E is applied to the PNLC composition layer L110 in liquid form to thereby harden a photosensitive compound in the PNLC composition layer L110 in liquid form, and thus, an electro-optic sensor layer 110 is formed from the PNLC composition layer L110 in liquid form. As a result, a modulator assembly MA1, which includes the electro-optic sensor layer 110 formed in the space limited by the spacer 112, the transparent electrode layer 120, and the reflective layer 130, is obtained. The transparent electrode layer 120 is on the lower surface of the electro-optic sensor layer 110, and the reflective layer 130 is on the upper surface of the electro-optic sensor layer 110.

For example, UV light may be radiated to generate the activation energy E. By radiating the UV light, the photosensitive compound in the PNLC composition layer L110 in liquid form is cross-linked or polymerized. As a result, as illustrated in FIGS. 2A and 2B, the electro-optic sensor layer 110, which is formed of a PNLC including a polymer network PN and a liquid crystal material LC stabilized by the polymer network PN, may be obtained.

In some embodiments, if a solvent is included in the PNLC composition layer L110 in liquid form (refer to FIG. 5J), a process of drying the PNLC composition layer L110 in liquid form and thus volatilizing the solvent may be further included before applying the activation energy E to the PNLC composition layer L110 in liquid form. For example, the drying may be performed for about 1 minute to about 10 minutes under a temperature of about 80° C. to about 130° C.

In some embodiments, light having a wavelength of about 365 nm may be radiated for about 60 seconds with an intensity of about 20 mW/cm² in the UV light radiation process. However, this condition is only an example, and the inventive concepts are not limited thereto.

Referring to FIG. 5L, by cooling a resultant structure obtained in the process of FIG. 5K up to a temperature at which the adhesive strength of the first and second carrier fixing adhesive layers 514 and 524 is relieved, the first carrier substrate 512, the first carrier fixing adhesive layer 514, the second carrier substrate 522, and the second carrier fixing adhesive layer 524 are separated and removed from the modulator assembly MA1. Thus, in the modulator assembly MA1, an outer surface 120S1 of the transparent electrode layer 120 and an outer surface 130S1 of the reflective layer 130 are exposed.

An inner surface 120S2 of the transparent electrode layer 120 may be processed with UV ozone in the same manner as described with reference to FIG. 5F, and an inner surface 130S2 of the reflective layer 130 may be processed with UV ozone in the same manner as described with reference to FIG. 5D. Thus, in a state in which surface energies of the inner surfaces 120S2 and 130S2 are increased, the transparent electrode layer 120 and the reflective layer 130 may directly contact the electro-optic sensor layer 110. Accordingly, an adhesive strength between the transparent electrode layer 120 and the electro-optic sensor layer 110 and an adhesive strength between the reflective layer 130 and the electro-optic sensor layer 110 may be improved. Thus, an adhesive strength between the transparent electrode layer 120 and the electro-optic sensor layer 110 and an adhesive strength between the reflective layer 130 and the electro-optic sensor layer 110 may be increased. Accordingly, the thickness of the modulator assembly MA1 may be maintained uniform.

Referring to FIG. 5M, an optical glass 150 may be attached to the outer surface 120S1 of the transparent electrode layer 120 by using an adhesive layer 152. The optical glass 150 may be covered with a reflection prevention (anti-reflection) layer 160, and an exposed surface of the reflective layer 130 may be covered with a protective coating layer 140. Thus, the electro-optic modulator 100 as illustrated in FIG. 1 is formed.

In the methods of manufacturing an electro-optic modulator, described with reference to FIGS. 5A to 5M, a reflective surface having high uniformity and/or reduced micro-defects may be obtained by forming the reflective layer 130 with a coating method instead of a deposition method, and as a result, the performance of detecting defects of fine pixels may be remarkably improved. If the reflective layer 130 is formed by using a deposition method, it may not be possible to separate a support base substrate from the reflective layer 130 during a deposition process, and thus, the support base substrate used in the deposition process and the reflective layer 130 form an electro-optic modulator. However, in the methods described with reference to FIGS. 5A to 5M, the base substrate 502 used for support during the coating process is removed from the reflective layer 130 after forming the reflective layer 130 with a coating method, and the modulator assembly MA1 having a structure in which the reflective layer 130 and the transparent electrode layer 120 cover both surfaces of the electro-optic sensor layer 110 may be formed. Accordingly, a separation distance between the electro-optic sensor layer 110 including a liquid crystal and an electrode of a TFT array, i.e., a defective pixel detection target, may decrease, and thus, defective pixel detection sensitivity may be improved. In addition, the inner surface 120S2 of the transparent electrode layer 120 and the inner surface 130S2 of the reflective layer 130 each may be processed with UV ozone, and thus, in a state in which surface energies of the inner surfaces 120S2 and 130S2 are increased, the transparent electrode layer 120 and the reflective layer 130 directly contact the electro-optic sensor layer 110. Accordingly, an adhesive strength between the transparent electrode layer 120 and the electro-optic sensor layer 110 and an adhesive strength between the reflective layer 130 and the electro-optic sensor layer 110 may be improved. Thus, an adhesive strength between the transparent electrode layer 120 and the electro-optic sensor layer 110 and an adhesive strength between the reflective layer 130 and the electro-optic sensor layer 110 may be increased. Accordingly, the thickness of the modulator assembly MA1 may be maintained uniform.

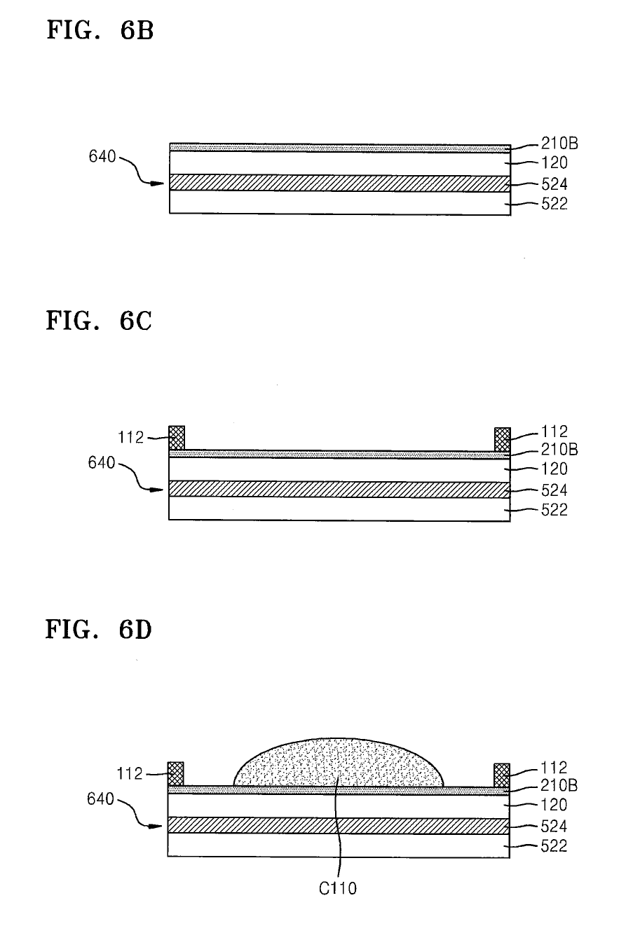

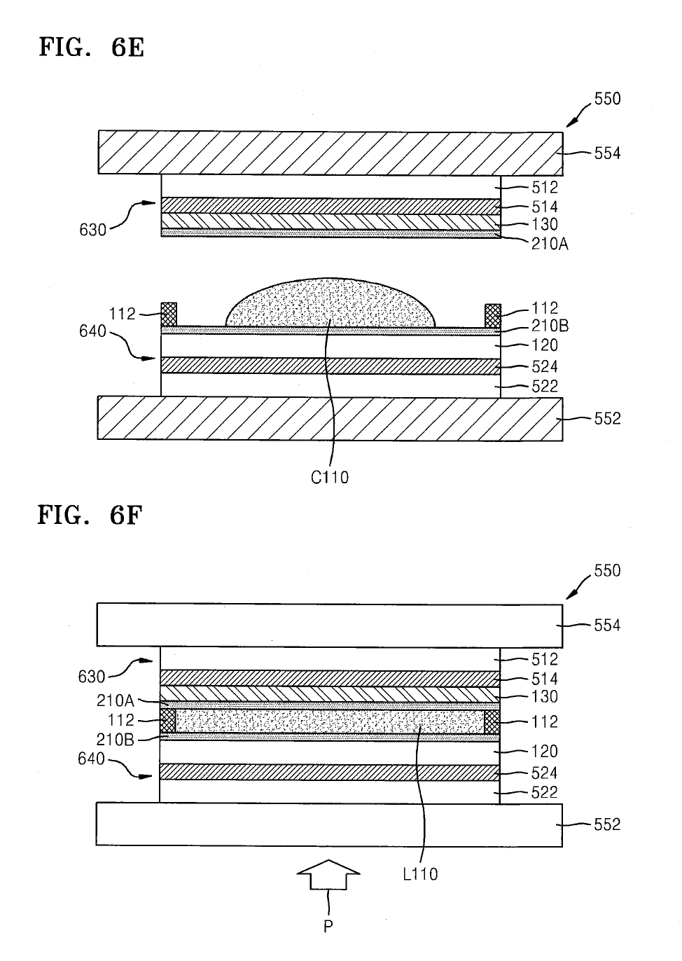

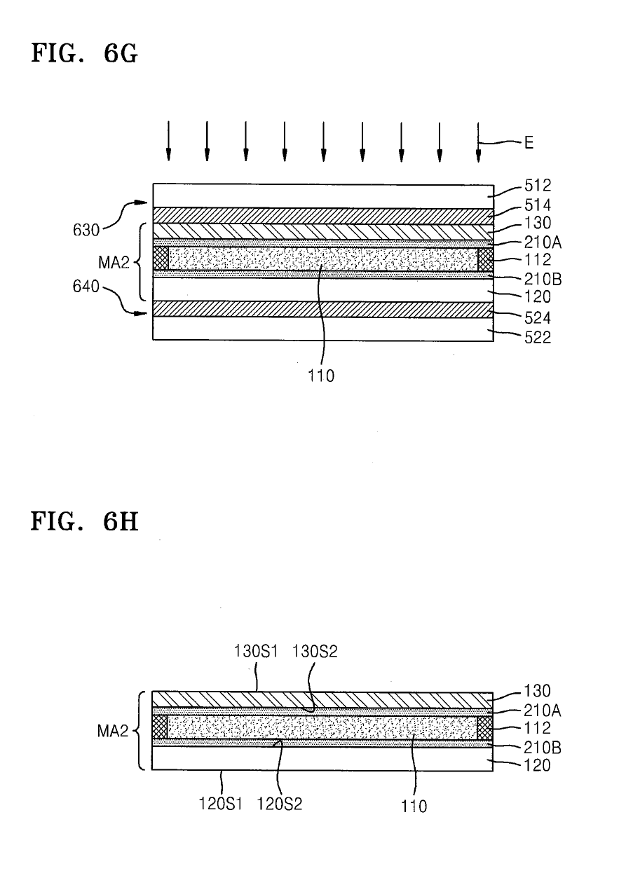

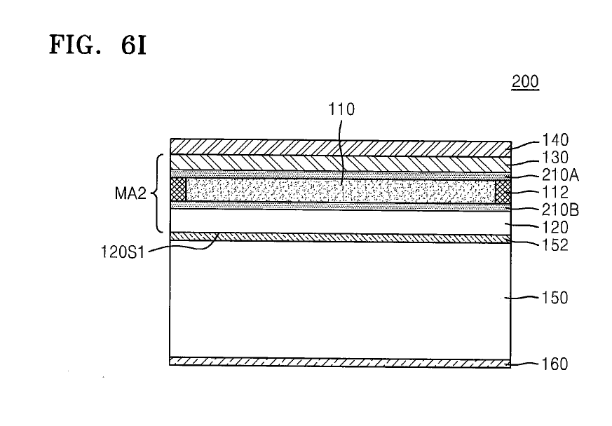

FIGS. 6A to 6I are cross-sectional views illustrated according to a process sequence of a method of manufacturing an electro-optic modulator, according to further embodiments of the inventive concept. In FIGS. 6A to 6I, exemplary methods for manufacturing the electro-optic modulator 200 illustrated in FIG. 4, including adhesion reinforcing layers 210A, 210B are illustrated. In FIGS. 6A to 6I, the same reference numerals as FIGS. 1 to 5M denote the same elements as FIGS. 1 to 5M. Thus, repeated descriptions thereof will not be given.

Referring to FIG. 6A, a reflective layer 130 is fixed onto a first carrier substrate 512 by using a first carrier fixing adhesive layer 514, according to the same method as described with reference to FIGS. 5A to 5C.

Then, a first adhesion reinforcing layer 210A is formed on an exposed surface of the reflective layer 130 to thereby form a reflective layer fixing structure 630.

A detailed configuration and effects of the first adhesion reinforcing layer 210A are as those described with reference to FIG. 4.

Referring to FIG. 6B, a transparent electrode layer 120 is fixed onto a second carrier substrate 522 by using a second carrier fixing adhesive layer 524, according to the same method as described with reference to FIGS. 5E and 5F.

Then, a second adhesion reinforcing layer 210B is formed on an exposed surface of the transparent electrode layer 120 to thereby form an electrode fixing structure 640.

A detailed configuration and effects of the second adhesion reinforcing layer 210B are as those described with reference to FIG. 4.

Referring to FIG. 6C, a spacer 112 is formed in the electrode fixing structure 640 and covers an edge portion of the exposed upper surface of the transparent electrode layer 120.

The spacer 112 may have the same shape and configuration as described with reference to FIG. 3. The thickness of the electro-optic sensor layer 110 to be formed in a subsequent process may be determined by the thickness of the spacer 112.

Referring to FIG. 6D, a PNLC composition C110 in liquid form is coated, by a predetermined amount, on an area of the upper surface of the second adhesion reinforcing layer 210B covering the transparent electrode layer 120, the area being limited by the spacer 112.

Details of the PNLC composition C110 in liquid are the same as those described with reference to FIG. 5H.

Referring to FIG. 6E, in a state in which the PNLC composition C110 in liquid form is coated on the upper surface of the second adhesion reinforcing layer 210B covering the transparent electrode layer 120 in the electrode fixing structure 640, the electrode fixing structure 640 and the reflective layer fixing structure 630 are positioned between a lower pressing member 552 and an upper pressing member 554 of uniform pressure equipment 550. In this case, the transparent electrode layer 120 of the electrode fixing structure 640 and the reflective layer 130 of the reflective layer fixing structure 630 are positioned so as to be aligned facing each other.

Referring to FIG. 6F, a joining process, by which pressure P is applied to the lower pressing member 552 so that the lower pressing member 552 moves to the upper pressing member 554 and thus the spacer 112 meets the reflective layer 130, is performed in the same manner described with reference to FIG. 5J.

As a result, the PNLC composition C110 coated on the upper surface of the second adhesion reinforcing layer 210B covering the transparent electrode layer 120 is pressed by the reflective layer fixing structure 630, and thus, a PNLC composition layer L110 in liquid form, which fills a space, which is limited by the first adhesion reinforcing layer 210A, the second adhesion reinforcing layer 210B, and the spacer 112, is formed between the transparent electrode layer 120 and the reflective layer 130.

Referring to FIG. 6G, after relieving the pressure P applied to the lower pressing member 552, the electrode fixing structure 540 and the reflective layer fixing structure 530, which are aligned facing each other with the spacer 112 and the PNLC composition layer L110 interposed therebetween, are separated from the uniform pressure equipment 550.

Then, activation energy E is applied to the PNLC composition layer L110 in liquid form to thereby harden a photosensitive compound in the PNLC composition layer L110 in liquid form (refer to FIG. 6F), and thus, an electro-optic sensor layer 110 is formed from the PNLC composition layer L110 in liquid form (refer to FIG. 6G). As a result, a modulator assembly MA2 is obtained. The modulator assembly MA2 includes the electro-optic sensor layer 110 formed in the space limited by the spacer 112, the reflective layer 130 facing the electro-optic sensor layer 110 with the first adhesion reinforcing layer 210A interposed therebetween at one side of the electro-optic sensor layer 110, and the transparent electrode layer 120 facing the electro-optic sensor layer 110 with the second adhesion reinforcing layer 210B interposed therebetween at the other side of the electro-optic sensor layer 110.

Referring to FIG. 6H, by cooling a resultant structure obtained in the process of FIG. 6G up to a temperature at which the adhesive strength of the first and second carrier fixing adhesive layers 514 and 524 is relieved, the first carrier substrate 512, the first carrier fixing adhesive layer 514, the second carrier substrate 522, and the second carrier fixing adhesive layer 524 are separated and removed from the modulator assembly MA2. Thus, in the modulator assembly MA2, an outer surface 120S1 of the transparent electrode layer 120 and an outer surface 130S1 of the reflective layer 130 are exposed.

Since an inner surface 130S2 of the reflective layer 130 is covered with the first adhesion reinforcing layer 210A and an inner surface 120S2 of the transparent electrode layer 120 is covered with the second adhesion reinforcing layer 210B, an adhesive strength between the reflective layer 130 and the electro-optic sensor layer 110 and an adhesive strength between the transparent electrode layer 120 and the electro-optic sensor layer 110 may be improved, and thus, an adhesive strength between the reflective layer 130 and the electro-optic sensor layer 110 and an adhesive strength between the transparent electrode layer 120 and the electro-optic sensor layer 110 may be increased. Accordingly, the thickness of the modulator assembly MA2 may be maintained uniform.

Referring to FIG. 6I, as described with reference to FIG. 5M, an optical glass 150 is attached to the outer surface 120S1 of the transparent electrode layer 120 by using an adhesive layer 152 and is covered with a reflection prevention layer 160, and an exposed surface of the reflective layer 130 is covered with a protective coating layer 140, and thus, the electro-optic modulator 200 as illustrated in FIG. 4 is formed.

In the methods of manufacturing an electro-optic modulator, described with reference to FIGS. 6A to 6I, a reflective surface having high uniformity and/or reduced micro-defects may be obtained by using a coating method when forming the reflective layer 130, similar to the method described with reference to FIGS. 5A to 5M, and as a result, pixel defect detection performance may be remarkably improved. In addition, by forming the modulator assembly MA2 including the transparent electrode layer 120 and the reflective layer 130, which cover both surfaces of the electro-optic sensor layer 110, after forming the reflective layer 130 with a coating method and then removing the base substrate 502 used for support during the coating process, a separation distance between the electro-optic sensor layer 110 including a liquid crystal and an electrode of a TFT array, i.e., a defective pixel detection target, may decrease, and thus, a defective pixel detection sensitivity may be improved. In addition, by forming the first adhesion reinforcing layer 210A between the reflective layer 130 and the electro-optic sensor layer 110 and the second adhesion reinforcing layer 210B between the transparent electrode layer 120 and the electro-optic sensor layer 110 with a very small thickness of about several nm to about several tens of nm, the adhesive strength between the reflective layer 130 and the electro-optic sensor layer 110 and the adhesive strength between the transparent electrode layer 120 and the electro-optic sensor layer 110 may be reinforced, and thus, the modulator assembly MA2 having a stack structure, in which the transparent electrode layer 120, the electro-optic sensor layer 110, and the reflective layer 130 are stacked in this order, may maintain a highly uniform thin film form.

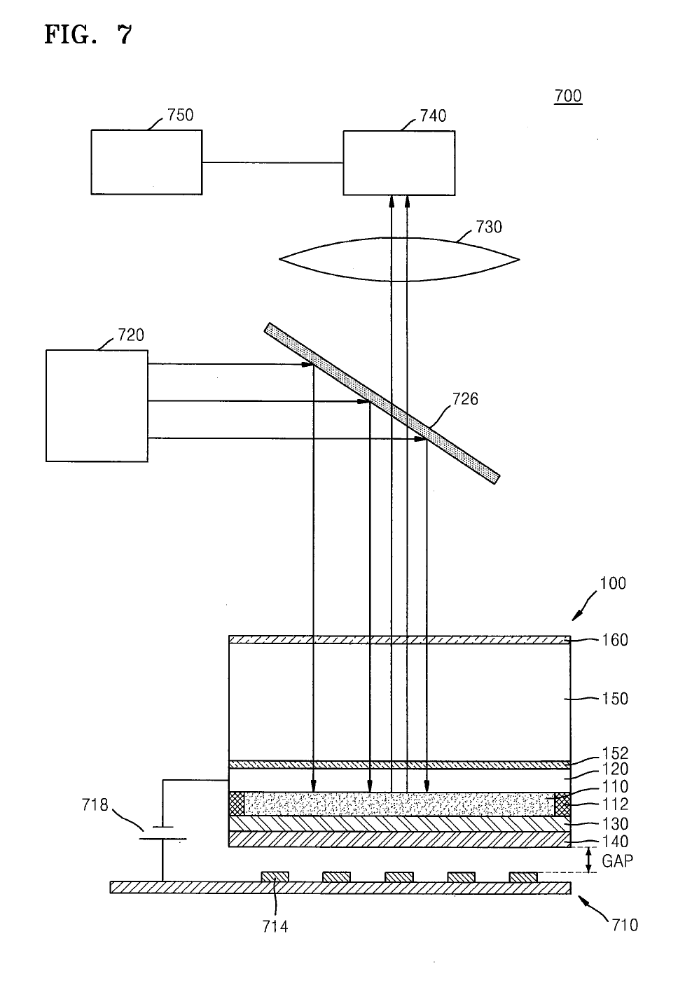

FIG. 7 is a diagram of a simplified main structure of a TFT array test apparatus 700 according to some embodiments of the inventive concepts.

Referring to FIG. 7, the TFT array test apparatus 700 includes a light source 720, an electro-optic modulator 100, a reflected light sensor 740, and an image processor 750.

The TFT array test apparatus 700 may detect the voltage distribution of a test target device 710, for example, a TFT panel including a TFT array, in a non-contact manner when the electro-optic modulator 100 is positioned above the test target device 710 with an air gap GAP therebetween, and thus, may detect and test an electrical defect of a plurality of pixel electrodes 714 of the test target device 710 based on the detected voltage distribution. In some embodiments, the air gap GAP may be from about 30 μm to about 50 μm.

The electro-optic modulator 100 may be disposed above the test target device 710 to be separate from a front side of the test target device 710 by a predetermined distance.

Light generated from the light source 720 may be radiated toward the electro-optic modulator 100 positioned above the test target device 710 by a beam splitter 726. A xenon (Xe) lamp, a sodium (Na) lamp, a halogen lamp, a laser, or the like may be used as the light source 720. Although not illustrated, a light collecting device or a mirror may be further installed in a light path between the light source 720 and the beam splitter 726.

The light received from the light source 720 is incident on the electro-optic sensor layer 110 through the optical glass 150 of the electro-optic modulator 100, and light reflected from the reflective layer 130 after passing through the electro-optic sensor layer 110 is output to the upper side of the electro-optic modulator 100 through the optical glass 150.

The TFT array test apparatus 700 includes a power supply for applying a voltage between the plurality of pixel electrodes 714 of the test target device 710 and the transparent electrode 120 of the electro-optic modulator 100. The test target device 710 may be disposed so that a predetermined distance is maintained between the transparent electrode layer 120 and the plurality of pixel electrodes 714 of the test target device 710, and an electric field may be formed between the plurality of pixel electrodes 714 and the transparent electrode layer 120 by applying a predetermined voltage to each of them by a power supply 718.

In the electro-optic modulator 100 included in the TFT array test device 700, the base substrate 502 (refer to FIGS. 5A and 5B) used for support during the coating process is removed from the reflective layer 130 after forming the reflective layer 130 with a coating method, and the modulator assembly MA1 (refer to FIG. 5K) including the reflective layer 130 is formed. Accordingly, a separation distance between the electro-optic sensor layer 110 and the plurality of pixel electrodes 714 of the test target device 710 may decrease by a thickness corresponding to the base substrate 502, and thus, defective pixel detection sensitivity may be improved.

The electro-optic sensor layer 110 of the electro-optic modulator 100 may be disposed between the transparent electrode layer 120 and the plurality of pixel electrodes 714 so that the amount of light passing through the electro-optic sensor layer 110 is changed according to the size of the electric field formed between the transparent electrode 120 and the plurality of pixel electrodes 714.

The reflected light sensor 740 may measure reflected light that passes through the electro-optic sensor layer 110 of the electro-optic modulator 100 and then is received through a collection optic device 730, and may generate image information depending on the size of a voltage in each of the plurality of pixel electrodes 714 based on the amount of the measured reflected light.

In some embodiments, the reflected light sensor 740 may include a charge-coupled device (CCD) camera.

The image processor 750 may analyze the image information generated by the reflected light sensor 740 to thereby detect the voltage distribution of each of the plurality of pixel electrodes 714.

In the TFT array test apparatus 700, a function of the electro-optic modulator 100 is based on light scattering characteristics of the liquid crystal material LC (refer to FIGS. 2A and 2B) in the electro-optic sensor layer 110. The electro-optic modulator 100 is positioned above the test target device 710 (for example, above the surface of a TFT array) with the air gap GAP therebetween, and the intensity of an electric field that is formed in the liquid crystal material LC in the electro-optic sensor layer 110 is changed according to the size of a voltage that is formed on the surface of the test target device 710. The change of the intensity of the electric field changes the transmittance of the liquid crystal material LC in the electro-optic sensor layer 110, and the voltage distribution on the surface of the test target device 710 may be indirectly measured by measuring the change of the transmittance. In order to measure the change of the transmittance, light generated from the light source 720 is incident on the electro-optic modulator 100 and light, which is reflected from the reflective layer 130 after passing through the elector-optic sensor layer 110 of the electro-optic modulator 100, is measured by the reflected light sensor 740. In the case of detecting a defective pixel through the measurement of reflected light, detection sensitivity is mainly determined by the liquid crystal sensitivity of the electro-optic sensor layer 110 and the uniformity of the reflective layer 130.

Since the electro-optic sensor layer 110 included in the electro-optic modulator 100 is formed of a PNLC including a liquid crystal material stabilized by a polymer network having a three-dimensional net structure from an outer surface of the electro-optic sensor layer 110 to an inner surface thereof and does not include a polymer matrix for fixing the PNLC, polymer content in the electro-optic sensor layer 110 is relatively low, and thus, a change in liquid crystal transmittance with respect to a minute voltage change, that is, liquid crystal sensitivity, may be improved. Accordingly, the contrast ratio of a liquid crystal during a voltage ON or OFF is maximized, and thus, the electro-optic sensor layer 110 may be advantageously used in detecting a pixel having a fine pitch and minimize a liquid crystal driving voltage.

In addition, by forming the reflective layer 130 of the electro-optic modulator 100 by using a coating method, the reflective layer 130 may maintain a highly uniform thin film form and have a remarkably low probability of micro-defect generation, compared to a reflective layer formed by using a PVD process or an E-beam evaporation process. In addition, as a highly uniform reflective layer is provided, the performance of detecting defects of fine pixels may be remarkably improved.

Although the TFT array test apparatus 700 including the electro-optic modulator 100 illustrated in FIG. 1 is described above as an example with reference to FIG. 7, a TFT array test apparatus including the electro-optic modulator 200 illustrated in FIG. 4 or another electro-optic modulator that is modified or changed from the electro-optic modulator 100 or 200 within the scope of the inventive concepts may also be included in a TFT array test apparatus according to the inventive concept. Each of the TFT array test apparatuses may provide the above-described effects according to the inventive concept.

An electro-optic modulator according to any of the above embodiments of the inventive concepts and a TFT array test apparatus including the same may remarkably improve the performance of detecting defective pixels by accurately detecting an electrical defect of a TFT array including a plurality of pixels repeatedly formed to have a fine pitch that is equal to or less than 30 μm.

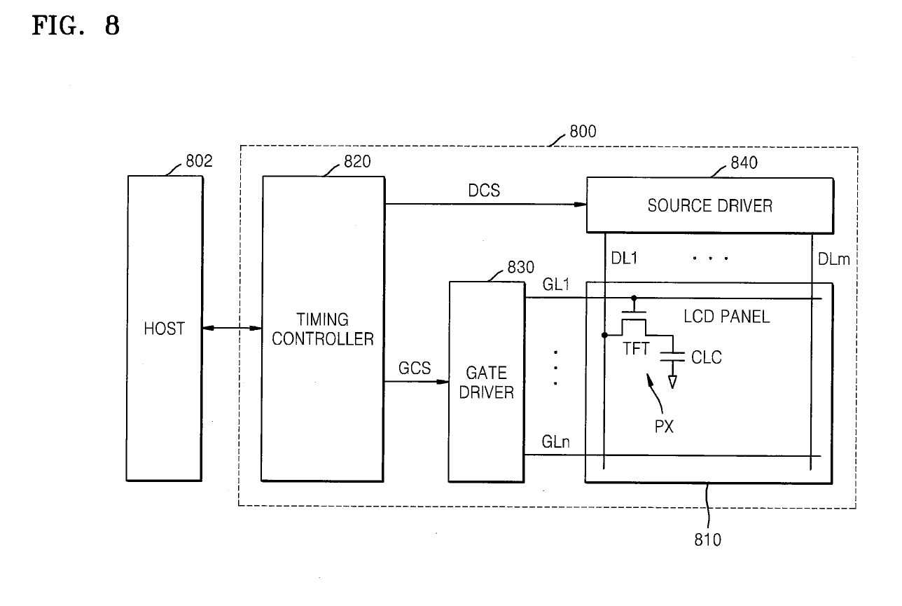

FIG. 8 is a block diagram of a liquid crystal display device 800 according to some embodiments of the inventive concept.

Referring to FIG. 8, the liquid crystal display device 800 includes a liquid crystal panel 810, a timing controller 820, a gate driver 830, and a source driver 840.

The liquid crystal panel 810 includes a plurality of gate lines GL1, . . . , GLn, a plurality of data lines DL1, . . . , DLm, and a plurality of pixels PX having a matrix form that is defined by the intersection of the plurality of gate lines GL1, . . . , GLn and the plurality of data lines DL1, . . . , DLm.

The plurality of pixels PX may have the same configuration and function. For convenience, one pixel PX is illustrated in FIG. 8. Each of the plurality of pixels PX includes a TFT and a liquid crystal capacitor CLC. A gate of the TFT is connected to a gate line corresponding thereto. A source of the TFT is connected to a data line corresponding thereto. The liquid crystal capacitor CLC is connected to the drain of the TFT.

The timing controller 820 may receive an external signal from a host 802. The external signal may include an image signal and a reference signal. The reference signal may be a signal synchronized with a frame frequency, for example, a vertical synchronization signal or a horizontal synchronization signal. The timing controller 820 may convert the received external signal into a gate control signal GCS and a data control signal DCS.

The timing controller 820 may output the gate control signal GCS to the gate driver 830. In addition, the timing controller 820 may output the data control signal DCS to the source driver 840. The timing controller 820 may control the gate driver 830 and the source driver 840 via the gate control signal GCS and the data control signal DCS, respectively.

The gate driver 830 may sequentially apply a gate signal to the plurality of gate lines GL1, . . . , GLn of the liquid crystal panel 810, in response to the gate control signal GCS provided from the timing controller 820.

The source driver 840 may apply a data signal to the plurality of data lines DL1, . . . , DLm of the liquid crystal panel 810, in response to the data control signal DCS provided from the timing controller 820.

When a gate signal is sequentially applied from the gate driver 830 to the plurality of gate lines GL1, . . . , GLn, a data signal corresponding to a gate line to which the gate signal is applied may be applied from the source driver 840 to the plurality of data lines DL1, . . . , DLm. As the gate signal is sequentially applied to the plurality of gate lines GL1, . . . , GLn during one frame, an image of one frame may be displayed. When a gate signal is applied to a gate line GL1 selected from the plurality of gate lines GL1, . . . , GLn, a TFT connected to the gate line GL1 may be turned on in response to the applied gate signal. When a data signal is applied to a data line DL1 connected to the turned-on TFT, the applied data signal may be charged to the liquid crystal capacitor CLC through the turned-on TFT. As the TFT is repeatedly turned on and off, the data signal may be charged to and discharged from the liquid crystal capacitor CLC. Since the light transmittance of a liquid crystal is adjusted according to a voltage charged to the liquid crystal capacitor CLC, a liquid crystal panel may be driven based on the adjusted light transmittance.

The plurality of pixels PX of the liquid crystal panel 810 may be obtained through an electrical test by using the TFT array test apparatus 700 described with reference to FIG. 7 or a TFT array test apparatus that is modified or changed from the TFT array test apparatus 700 within the scope of the inventive concept, and may be repeatedly arranged at a pitch of 30 μm or less.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed typical embodiments and, although specific terms are employed, they are used in a generic and descriptive sense only and not for purposes of limitation, the scope of the inventive concepts being set forth in the following claims.

What is claimed is:

1. An electro-optic modulator comprising:
an electro-optic sensor layer comprising a liquid crystal stabilized by a polymer network having a three-dimensional mesh structure that extends from a first surface of the electro-optic sensor layer to a second surface of the electro-optic sensor layer that is opposite to the first surface of the electro-optic sensor layer;
a transparent electrode layer on the first surface of the electro-optic sensor layer; and
a reflective layer on the second surface of the electro-optic sensor layer.

2. The electro-optic modulator of claim 1, wherein at least one of the transparent electrode layer and the reflective layer directly contacts the polymer network of the electro-optic sensor layer.

3. The electro-optic modulator of claim 1, further comprising an adhesion reinforcing layer between the electro-optic sensor layer and one of the transparent electrode layer and the reflective layer.

4. The electro-optic modulator of claim 3, wherein the adhesion reinforcing layer comprises a silicon oxide layer.

5. The electro-optic modulator of claim 1, wherein the reflective layer comprises an insulating layer including metal nanoparticles.

6. The electro-optic modulator of claim 1, wherein the reflective layer comprises a plurality of plasmon particles having a size of from about 10 nm to about 500 nm.

7. The electro-optic modulator of claim 6, wherein the plurality of plasmon particles comprise a composite shell including a metal core with an insulating shell surrounding the metal core, or an insulating core with a metal shell surrounding the insulating core.

8. The electro-optic modulator of claim 1, wherein the reflective layer comprises an inner surface facing the electro-optic sensor layer and an outer surface that is opposite to the inner surface, and
wherein the electro-optic modulator further comprises a protective coating layer directly contacts the outer surface of the reflective layer.

9. The electro-optic modulator of claim 1, further comprising a spacer interposed between the transparent electrode layer and the reflective layer, the spacer defining a region of the electro-optic sensor layer between the transparent electrode layer and the reflective layer.

10. The electro-optic modulator of claim 9, wherein a thickness of the spacer is equal to a thickness of the electro-optic sensor layer.

11. The electro-optic modulator of claim 1, wherein the transparent electrode layer comprises an inner surface facing the electro-optic sensor layer and an outer surface that is opposite to the inner surface, and
wherein the electro-optic modulator further comprises an optical glass on the outer surface of the transparent electrode layer.

12. The electro-optic modulator of claim 1, wherein the electro-optic sensor layer comprises a polymer network liquid crystal (PNLC).

13. A thin film transistor (TFT) array test apparatus comprising:
a light source;
an electro-optic modulator comprising an electro-optic sensor layer, a transparent electrode layer on the electro-optic sensor layer, and a reflective layer on the electro-optic sensor layer opposite the transparent electrode layer, wherein the electro-optic sensor layer comprises a liquid crystal stabilized by a polymer network having a three-dimensional mesh structure that extends from a first surface of the electro-optic sensor layer to a second surface of the electro-optic sensor layer;
a power supply configured to apply a voltage between the transparent electrode layer and a plurality of pixel electrodes forming a TFT array of a test target object; and
a light sensor configured to measure light reflected from the electro-optic modulator.

14. The TFT array test apparatus of claim 13, wherein the electro-optic modulator reflects light, received from the light source, through the electro-optic sensor layer responsive to a voltage distribution of each of the plurality of pixel electrodes.

15. The TFT array test apparatus of claim 13, wherein the transparent electrode layer and the reflective layer each directly contact the polymer network of the electro-optic sensor layer.

16. The TFT array test apparatus of claim 13, wherein the electro-optic modulator further comprises:
a first adhesion reinforcing layer between the electro-optic sensor layer and the reflective layer; and
a second adhesion reinforcing layer between the electro-optic sensor layer and the transparent electrode layer.

17. The TFT array test apparatus of claim 13, further comprising an image processor configured to analyze image information generated by the light sensor to thereby detect the voltage distribution of each of the plurality of pixel electrodes.

18. An electro-optic modulator comprising:
a transparent electrode layer;
a reflective layer on the transparent electrode layer;
a spacer between the transparent electrode layer and the reflective layer, the spacer contacting edge portions of the transparent electrode layer and the reflective layer to define a region within the edge portions between the transparent electrode layer and the reflective layer; and
an electro-optic sensor layer in the region defined by the spacer between the transparent electrode layer and the reflective layer, the electro-optic sensor layer comprising a liquid crystal stabilized by a polymer network having a three-dimensional mesh structure that extends from a first surface of the electro-optic sensor layer proximate the transparent electrode layer to a second surface of the electro-optic sensor layer proximate the reflective layer.

19. The electro-optic modulator of claim 18, further comprising:
a first adhesion reinforcing layer between the electro-optic sensor layer and the reflective layer; and
a second adhesion reinforcing layer between the electro-optic sensor layer and the transparent electrode layer.

20. The electro-optic modulator of claim 18, wherein at least one of the transparent electrode layer and the reflective layer directly contacts the polymer network of the electro-optic sensor layer.
